(19) United States
(12) Patent Application Publication
(10) Pub. No.: US 2026/0194341 A1
(43) Pub. Date: Jul. 9, 2026

(54) CALIBRATION METHOD AND APPARATUS

(71) Applicant: ASML Netherlands B.V., Veldhoven (NL)

(72) Inventors: Sjoerd Nicolaas Lambertus DONDERS, Vught (NL); Carsten MÄDLER, Utrecht (NL); Peter Fernand William Jozef DENDAS, Koersel (BE)

(73) Assignee: ASML Netherlands B.V., Veldhoven (NL)

(21) Appl. No.: 18/868,800

(22) PCT Filed: May 12, 2023
(86) PCT No.: PCT/EP2023/062745

§ 371 Date: Nov. 25, 2024

(30) Foreign Application Priority Data
Jun. 16, 2022 (EP) 22179381.3

(51) Int. Cl. G01B 11/06; G01Q 60/24; G03F 7/00

(52) U.S. Cl. CPC G01B 11/0608; G01Q 60/24; G03F 7/70625; G03F 7/70655; G03F 7/706837; G03F 7/706845; G03F 7/706847

(57) ABSTRACT

A method for calibrating a height measuring optical sensor for a substrate in a lithographic apparatus. The method comprises determining, using the height measuring optical sensor, a first height of a surface of the substrate within a region of interest. The method further comprises determining, using a scanning probe microscope, a second height of the surface of the substrate within the region of interest. The method further comprises determining a calibration map for the height measuring optical sensor for the region of interest, by comparing the first height and the second height.

### CROSS-REFERENCE TO RELATED APPLICATION

The application claims priority of EP application 22179381.3 which was filed on 16 Jun., 2022 and which is incorporated herein in its entirety by reference.

### FIELD

The present invention relates to a method for calibrating a height measuring optical sensor, the height measuring optical sensor configured to measure the height of a substrate, and associated apparatus for carrying out the method.

### BACKGROUND

A lithographic apparatus is a machine constructed to apply a desired pattern onto a substrate. A lithographic apparatus can be used, for example, in the manufacture of integrated circuits (ICs). A lithographic apparatus may, for example, project a pattern (also often referred to as “design layout” or “design”) of a patterning device (e.g., a mask also referred to as a reticle) onto a layer of radiation-sensitive material (resist) provided on a substrate (e.g., a wafer).

As semiconductor manufacturing processes continue to advance, the dimensions of circuit elements have continually been reduced while the amount of functional elements, such as transistors, per device has been steadily increasing over decades, following a trend commonly referred to as ‘Moore's law’. To keep up with Moore's law the semiconductor industry is chasing technologies that enable to create increasingly smaller features. To project a pattern on a substrate a lithographic apparatus may use electromagnetic radiation. The wavelength of this radiation determines the minimum size of features which are patterned on the substrate. Typical wavelengths currently in use are 365 nm (i-line), 248 nm, 193 nm and 13.5 nm. A lithographic apparatus, which uses extreme ultraviolet (EUV) radiation, having a wavelength within a range of 4 nm to 20 nm, for example 6.7 nm or 13.5 nm, may be used to form smaller features on a substrate than a lithographic apparatus which uses, for example, radiation with a wavelength of 193 nm.

Typically, the substrate may include multiple layers (each layer having been patterned by a reticle) and each of the layers may comprise multiple repetitions of the same pattern, the patterns being arranged as a two-dimensional array. As a result, the substrate comprises a two-dimensional array of multiple copies of the same pattern (the pattern itself being a three-dimensional pattern).

Different points across a surface of the substrate may be at different heights and so lithographic radiation focused on the surface of the substrate at a first point (at a first height) may not be in focus at a second point (at a second height). To maintain focus on the substrate surface, the height of the surface of the substrate is measured and corresponding corrections are made.

The height of the surface of the substrate may be measured using a height measuring optical sensor. However, it is known that light (used by height measuring optical sensors to measure the height of the surface of the substrate) may penetrate partially into the substrate surface instead of being reflected solely by the substrate surface, resulting in a measurement error. It is also known that an air gauge (i.e. a sensor that uses flow of air to measure distance to an object) may be used as a secondary measure of the height of the surface of the substrate, for example, to provide a calibration for the height measuring optical sensor.

### SUMMARY

In a first example described herein there is a method for calibrating a height measuring optical sensor for a substrate in a lithographic apparatus comprising: determining, using the height measuring optical sensor, a first height of a surface of the substrate within a region of interest; determining, using a scanning probe microscope, a second height of the surface of the substrate within the region of interest; and determining a calibration map for the height measuring optical sensor for the region of interest, by comparing the first height and the second height.

The calibration map may comprise a plurality of calibration values, each calibration value corresponding to a point or area within the region of interest. The substrate may include multiple layers, each layer having been patterned by lithographic radiation patterned by a reticle (which may also be referred to as a mask). Each patterned layer comprises multiple repetitions of the same pattern, the patterns being arranged as a two-dimensional array. As a result, the substrate comprises a two-dimensional array of copies of the same pattern (the pattern itself being a three-dimensional pattern). The region of interest may be one such pattern. A pattern may be referred to as a field (or exposure field), indicating an area which will be exposed by the lithographic apparatus to form the next layer of the pattern. Each field may comprise one or more dies. In other words, the region of interest may correspond to a single die, or alternatively, multiple dies. Beneficially the method of calibration provides a method of calibrating the height measuring optical sensor thus allowing the height measuring optical sensor to measure the height of the surface of the substrate to a high level of accuracy. The region of interest may be one of a plurality of regions of interest.

The method may further comprise applying the calibration map for other regions of the substrate that corresponding to the region of interest. Regions that correspond to the region of interest are expected to interact with radiation of the height measuring optical sensor in the same way, and thus a calibration map determined for the region of interest may be also be beneficially applied to any other region that corresponds to the region of interest. For example, if the region of interest corresponds to a field, the calibration map may be applied to other corresponding fields across the substrate. Applying the calibration map may comprise applying an offset to the height of the substrate as measured by the height measuring optical sensor. The offset may be different at different positions on the region of interest. The resulting measurement may be used during lithographic exposure, when determining how to change the elevation (i.e. the z coordinate) of a substrate, for example, by adjusting a height of a substrate support on which the substrate is mounted. Additionally or alternatively, the resulting measurement may be used to adjust a focus of lithographic radiation, for example, by adjusting one or more optical elements of the lithographic apparatus.

The height measuring optical sensor may, in use, use UV radiation. The height measuring optical sensor may be referred to as a level sensor.

The scanning probe microscope may be an atomic force microscope (AFM) or a near-field scanning optical microscope (NSOM). Beneficially, the use of an AFM or an NSOM provides a high resolution second sensor that allow a precise calibration for the first sensor. Alternative to a scanning probe microscope, an air gauge may be used to determine the second height.

The scanning probe microscope may be one of a plurality of scanning probe microscopes. The plurality of scanning probe microscopes may be arranged into an array of scanning probe microscopes. Beneficially, the use of an array of scanning probe microscopes may allow the determination of the second height at multiple points (within the region of interest) at a single time, thereby decreasing the time taken to calibrate the first sensor.

Determining the second height may comprise: measuring, using the scanning probe microscope, a height of the surface of the substrate within the region of interest.

Determining the second height may further comprise: measuring, using the scanning probe microscope, plurality of heights of the surface of the substrate for the at least on region of interest; and calculating an average of the plurality of heights. Advantageously, the method may ensure that the measured second height (determined by the scanning probe microscope) is comparable with the second first height.

In a second example described herein there is a lithographic apparatus comprising: a height measuring optical sensor configured to determine a first height of a surface of the substrate within a region of interest; a scanning probe microscope configured to determine a second height of the surface of the substrate within the region of interest; and a processor configured to determine a calibration map for the height measuring optical sensor for the region of interest, by comparing the first height and the second height. In a lithographic apparatus, the substrate may be provided on a substrate support, and in use, the substrate support may move in the substrate in a scanning direction. An array of scanning probe microscopes may be provided such that the scanning probe microscopes are provided in a series which extends in a direction perpendicular to the scanning direction. Beneficially, providing a lithographic apparatus with hardware used to perform the calibration method simplifies the calibration process and allows in-situ measurements.

In a third example described herein there is a system comprising: a lithographic apparatus comprising a height measuring optical sensor configured to determine a first height of a surface of the substrate within a region of interest; a scanning probe microscope configured to determine a second height of the surface of the substrate within the region of interest; and a processor configured to determine a calibration map for the height measuring optical sensor for the region of interest, by comparing the first height and the second height.

In a fourth example described herein there is a lithographic tool comprising: a height measuring optical sensor configured to determine a first height of a surface of the substrate within a region of interest; a scanning probe microscope configured to determine a second height of the surface of the substrate within the region of interest; and a processor configured to determine a calibration map for the height measuring optical sensor for the region of interest, by comparing the first height and the second height.

In a fifth example described herein there is a metrology tool comprising: a height measuring optical sensor configured to determine a first height of a surface of the substrate within a region of interest; a scanning probe microscope configured to determine a second height of the surface of the substrate within the region of interest; and a processor configured to determine a calibration map for the height measuring optical sensor for the region of interest, by comparing the first height and the second height.

In a sixth example described herein there is a computer-readable storage medium comprising instructions which, when executed by a computer, cause the computer to carry out the method of the first example.

In a seventh example described herein there is a calibration map comprising data corresponding to a region of interest of a substrate wherein the substrate comprises a plurality of regions, each region of the plurality of regions having been patterned with an identical pattern. The calibration map may consist of data corresponding to a single region of interest only and the calibration map may be sufficient to allow for the calibration of other regions (patterned by the same identical pattern). Beneficially, the calibration map may be smaller in size and reduce computing overheads.

In an eighth example described herein there is a method of determining a height of a surface of a substrate comprising: determining a height of a reference point; and determining, using a plurality of scanning probe microscopes, the height of the surface of the substrate at one or more points.

The one or more points may each be located within a single region of the substrate. The single region may be a die or a field. The reference point may be, for example, a mark or a tab.

The plurality of scanning probe microscopes may be arranged into an array or lattice. For example, when arranged into a lattice the plurality of scanning probes may be arranged into a first row and a second row, and the second row may be offset relative to the first row. The plurality of scanning probe microscopes may be distributed such that the plurality of scanning probe microscopes extends across at least the combined width of a field and associated scribe lanes. Alternatively, the plurality of scanning probe microscopes may be distributed such that the plurality of scanning probe microscopes extends across at least the width of substrate and reference rails.

The substrate and the plurality of scanning probe microscopes may be moved with respect to one another.

The determined height of the surface of the substrate at the one or more points may be a relative height, relative to the height of a reference point.

In a ninth example described herein there is a lithographic apparatus comprising a plurality of scanning probe microscopes configured to: determine a height of a reference point; and determine the height of the surface of the substrate at one or more points.

In a tenth example described herein there is a metrology tool comprising a plurality of scanning probe microscopes configured to: determine a height of a reference point; and determine the height of the surface of the substrate at one or more points.

### BRIEF DESCRIPTION OF THE DRAWINGS

Embodiments of the invention will now be described, by way of example only, with reference to the accompanying schematic drawings, in which:

FIG. 1 depicts a schematic overview of a lithographic apparatus;

FIG. 2 depicts an example height measuring optical sensor;

FIG. 3 depicts an example substrate following exposure;

FIG. 4 depicts a flow diagram for a method for calibrating a height measuring optical sensor;

FIG. 5 depicts an example scanning probe microscope;

FIG. 6 depicts an example substrate with first and second height measurement points;

FIG. 7 depicts an example array of scanning probe microscopes configured to measure a height of a substrate; and

FIG. 8 depicts an example array of scanning probe microscopes configured to measure a height of a field.

### DETAILED DESCRIPTION

In the present document, the terms “radiation” and “beam” are used to encompass all types of electromagnetic radiation, including ultraviolet radiation (e.g. with a wavelength of 365, 248, 193, 157 or 126 nm) and EUV (extreme ultra-violet radiation, e.g. having a wavelength in the range of about 5-100 nm).

The term “reticle”, “mask” or “patterning device” as employed in this text may be broadly interpreted as referring to a generic patterning device that can be used to endow an incoming radiation beam with a patterned cross-section, corresponding to a pattern that is to be created in a target portion of the substrate. The term “light valve” can also be used in this context. Besides the classic mask (transmissive or reflective, binary, phase-shifting, hybrid, etc.), examples of other such patterning devices include a programmable mirror array and a programmable LCD array.

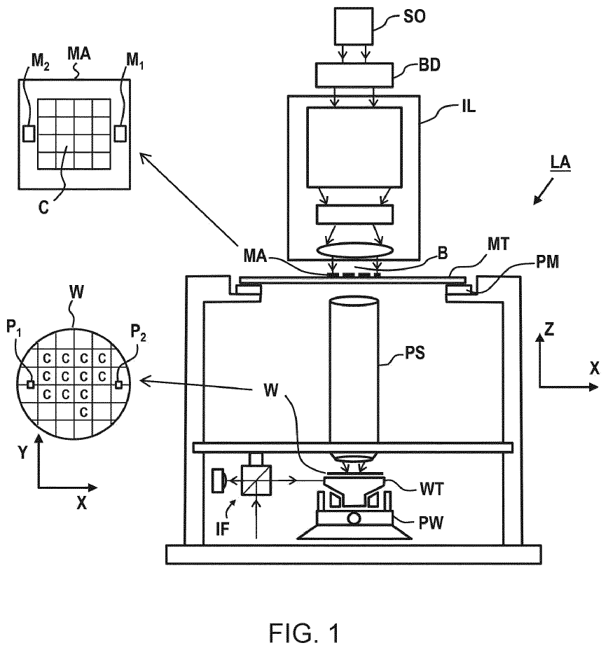

FIG. 1 schematically depicts a lithographic apparatus LA. The lithographic apparatus LA includes an illumination system (also referred to as illuminator) IL configured to condition a radiation beam B (e.g., UV radiation, DUV radiation or EUV radiation), a mask support (e.g., a mask table) MT constructed to support a patterning device (e.g., a mask) MA and connected to a first positioner PM configured to accurately position the patterning device MA in accordance with certain parameters, a substrate support (e.g., a wafer table) WT constructed to hold a substrate (e.g., a resist coated wafer) W and connected to a second positioner PW configured to accurately position the substrate support in accordance with certain parameters, and a projection system (e.g., a refractive projection lens system) PS configured to project a pattern imparted to the radiation beam B by patterning device MA onto a target portion C (e.g., comprising one or more dies) of the substrate W.

In operation, the illumination system IL receives a radiation beam from a radiation source SO, e.g. via a beam delivery system BD. The illumination system IL may include various types of optical components, such as refractive, reflective, magnetic, electromagnetic, electrostatic, and/or other types of optical components, or any combination thereof, for directing, shaping, and/or controlling radiation. The illuminator IL may be used to condition the radiation beam B to have a desired spatial and angular intensity distribution in its cross section at a plane of the patterning device MA.

The term “projection system” PS used herein should be broadly interpreted as encompassing various types of projection system, including refractive, reflective, catadioptric, anamorphic, magnetic, electromagnetic and/or electrostatic optical systems, or any combination thereof, as appropriate for the exposure radiation being used, and/or for other factors such as the use of an immersion liquid or the use of a vacuum. Any use of the term “projection lens” herein may be considered as synonymous with the more general term “projection system” PS.

The lithographic apparatus LA may be of a type wherein at least a portion of the substrate may be covered by a liquid having a relatively high refractive index, e.g., water, so as to fill a space between the projection system PS and the substrate W—which is also referred to as immersion lithography. More information on immersion techniques is given in U.S. Pat. No. 6,952,253, which is incorporated herein by reference.

The lithographic apparatus LA may also be of a type having two or more substrate supports WT (also named “dual stage”). In such “multiple stage” machine, the substrate supports WT may be used in parallel, and/or steps in preparation of a subsequent exposure of the substrate W may be carried out on the substrate W located on one of the substrate support WT while another substrate W on the other substrate support WT is being used for exposing a pattern on the other substrate W.

In addition to the substrate support WT, the lithographic apparatus LA may comprise a measurement stage. The measurement stage is arranged to hold a sensor and/or a cleaning device. The sensor may be arranged to measure a property of the projection system PS or a property of the radiation beam B. The measurement stage may hold multiple sensors. The cleaning device may be arranged to clean part of the lithographic apparatus, for example a part of the projection system PS or a part of a system that provides the immersion liquid. The measurement stage may move beneath the projection system PS when the substrate support WT is away from the projection system PS.

In operation, the radiation beam B is incident on the patterning device, e.g. mask, MA which is held on the mask support MT, and is patterned by the pattern (design layout) present on patterning device MA. Having traversed the mask MA, the radiation beam B passes through the projection system PS, which focuses the beam onto a target portion C of the substrate W. With the aid of the second positioner PW and a position measurement system IF, the substrate support WT can be moved accurately, e.g., so as to position different target portions C in the path of the radiation beam B at a focused and aligned position. Similarly, the first positioner PM and possibly another position sensor (which is not explicitly depicted in FIG. 1) may be used to accurately position the patterning device MA with respect to the path of the radiation beam B. Patterning device MA and substrate W may be aligned using mask alignment marks M1, M2 and substrate alignment marks P1, P2. Although the substrate alignment marks P1, P2 as illustrated occupy dedicated target portions, they may be located in spaces between target portions. Substrate alignment marks P1, P2 are known as scribe-lane alignment marks when these are located between the target portions C.

To clarify the invention, a Cartesian coordinate system is used. The Cartesian coordinate system has three axes, i.e., an x-axis, a y-axis and a z-axis. Each of the three axes is orthogonal to the other two axis. A rotation around the x-axis is referred to as an Rx-rotation. A rotation around the y-axis is referred to as an Ry-rotation. A rotation around about the z-axis is referred to as an Rz-rotation. The x-axis and the y-axis define a horizontal plane, whereas the z-axis is in a vertical direction. The Cartesian coordinate system is not limiting the invention and is used for clarification only. Instead, another coordinate system, such as a cylindrical coordinate system, may be used to clarify the invention. The orientation of the Cartesian coordinate system may be different, for example, such that the z-axis has a component along the horizontal plane.

A topography measurement system, level sensor or height sensor, and which may be integrated in the lithographic apparatus, is arranged to measure a topography of a top surface of a substrate (or wafer). The level sensor may also be referred to as a height measuring optical sensor. A map of the topography of the substrate, also referred to as height map, may be generated from these measurements indicating a height of the substrate as a function of the position on the substrate. This height map may subsequently be used to correct the position of the substrate during transfer of the pattern on the substrate, in order to provide an aerial image of the patterning device in a properly focus position on the substrate. It will be understood that “height” in this context refers to a dimension broadly out of the plane to the substrate (also referred to as Z-axis). Typically, the level or height sensor performs measurements at a fixed location (relative to its own optical system) and a relative movement between the substrate and the optical system of the level or height sensor results in height measurements at locations across the substrate.

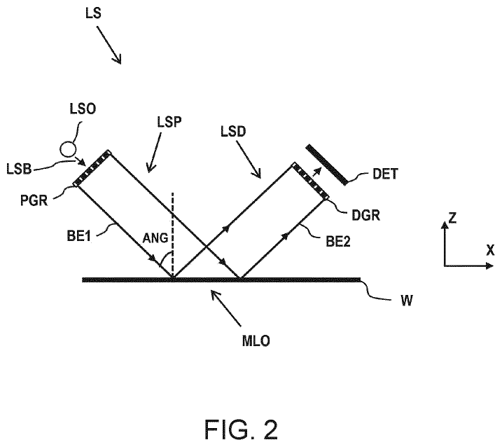

An example of a level or height sensor LS as known in the art is schematically shown in FIG. 2, which illustrates only the principles of operation. In this example, the level sensor comprises an optical system, which includes a projection unit LSP and a detection unit LSD. The projection unit LSP comprises a radiation source LSO providing a beam of radiation LSB which is imparted by a projection grating PGR of the projection unit LSP. The radiation source LSO may be, for example, a narrowband or broadband radiation source, such as a supercontinuum light source, polarized or non-polarized, pulsed or continuous, such as a polarized or non-polarized laser beam. The radiation source LSO may include a plurality of radiation sources having different colors, or wavelength ranges, such as a plurality of LEDs. The radiation source LSO of the level sensor LS is not restricted to visible radiation, but may additionally or alternatively encompass UV and/or IR radiation and any range of wavelengths suitable to reflect from a surface of a substrate.

The projection grating PGR is a periodic grating comprising a periodic structure resulting in a beam of radiation BE1 having a periodically varying intensity. The beam of radiation BE1 with the periodically varying intensity is directed towards a measurement location MLO on a substrate W having an angle of incidence ANG with respect to an axis perpendicular (Z-axis) to the incident substrate surface between 0 degrees and 90 degrees, typically between 70 degrees and 80 degrees. At the measurement location MLO, the patterned beam of radiation BE1 is reflected by the substrate W (indicated by arrows BE2) and directed towards the detection unit LSD.

In order to determine the height level at the measurement location MLO, the level sensor further comprises a detection system comprising a detection grating DGR, a detector DET and a processing unit (not shown) for processing an output signal of the detector DET. The detection grating DGR may be identical to the projection grating PGR. The detector DET produces a detector output signal indicative of the light received, for example indicative of the intensity of the light received, such as a photodetector, or representative of a spatial distribution of the intensity received, such as a camera. The detector DET may comprise any combination of one or more detector types.

By means of triangulation techniques, the height level at the measurement location MLO can be determined. The detected height level is typically related to the signal strength as measured by the detector DET, the signal strength having a periodicity that depends, amongst others, on the design of the projection grating PGR and the (oblique) angle of incidence ANG.

The projection unit LSP and/or the detection unit LSD may include further optical elements, such as lenses and/or mirrors, along the path of the patterned beam of radiation between the projection grating PGR and the detection grating DGR (not shown).

In an embodiment, the detection grating DGR may be omitted, and the detector DET may be placed at the position where the detection grating DGR is located. Such a configuration provides a more direct detection of the image of the projection grating PGR.

In order to cover the surface of the substrate W effectively, a level sensor LS may be configured to project an array of measurement beams BE1 onto the surface of the substrate W, thereby generating an array of measurement areas MLO or spots covering a larger measurement range.

Various height sensors of a general type are disclosed for example in U.S. Pat. No. 7,265,364 and 7,646,471, both incorporated by reference. A height sensor using UV radiation instead of visible or infrared radiation is disclosed in US2010233600A1, incorporated by reference. In WO2016102127A1, incorporated by reference, a compact height sensor is described which uses a multi-element detector to detect and recognize the position of a grating image, without needing a detection grating.

During use, the beam of radiation BE1 emitted by the projection unit LSP may interact with the surface of the substrate W in unpredictable ways. For example, the surface may be provided with multiple layers (each layer, other than the first, provided on top of another layer) and each layer may partially reflect the beam of radiation BE1. The methods used by the level sensor LS to determine the height level at the measurement location MLO may not be able to predict such measurement errors (such as those arising due to multiple partial reflections of the beam of radiation BE1) and therefore the determined height level may be inaccurate without calibration. While such measurement errors are difficult to predict, the effect (of the measurement errors) on the height level determined by the level sensor LS may be consistent. In other words, if the level sensor LS determines the height level of a single point multiple times, the level sensor LS should determine the same, or approximately the same, height level each time. Likewise, if there are multiple points on the surface of the substrate W that are of similar heights and that are provided with similar multiple layers, the level sensor LS should determine the same, or approximately the same, height levels for each point.

It is known that measurement errors described above are caused by optical effects (e.g. multiple partial reflections of the beam of radiation BE1) and should not arise when measuring the height of the surface of the substrate W using mechanical methods of measurement (e.g. using a gas gauge proximity sensor, such as an air gauge, described below). Accordingly, mechanical methods of measurement may be used in addition (to calibrate and reduce the measurement errors) or as an alternative to the level sensor LS.

An air gauge may determine the height of the surface of the substrate W by directing an outward air flow onto the surface and determining height by virtue of differential flow measurements relative to a reference. Height measurements determined by air gauges typically measure with nanometer accuracy, without suffering from unwanted optical interactions. Disadvantages of the air gauge include a very slow measurement process, and sensitivity to temperature and drift.

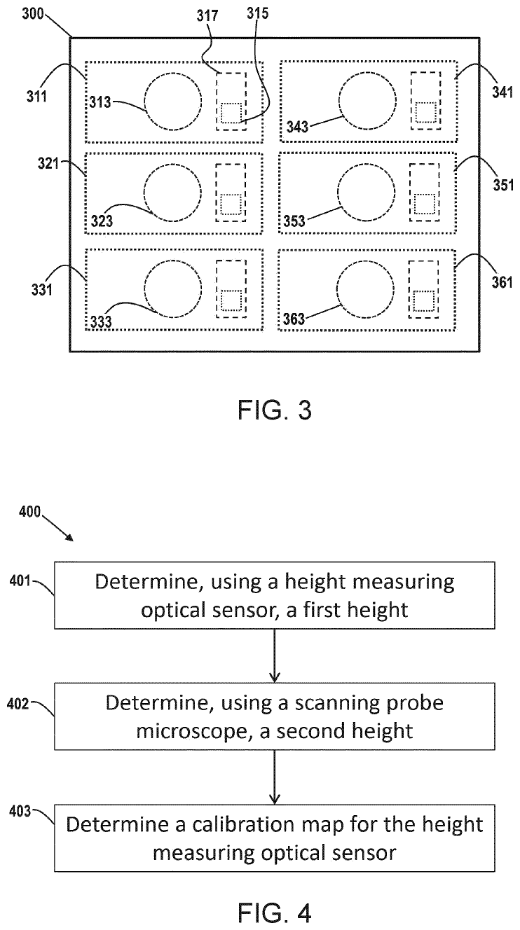

FIG. 3 depicts an example substrate 300 following exposure (to patterned lithographic radiation i.e. the radiation beam B). The substrate 300 may be the same as substrate W. The substrate may be circular or any other shape, although for ease of illustration it is depicted as rectangular.

The substrate 300 comprises multiple layers, each layer comprising processed structures having been patterned by lithographic radiation patterned by a reticle, and subsequently processed. Subsequent processing typically comprises developing the substrate to reveal the pattern (on the photo-resist), etching to reveal the pattern in the resist, depositing material onto the exposed resist and removing remaining resist. A new layer of resist is subsequently applied prior to a subsequent exposure of a pattern, and the processing steps are repeated. The skilled person will recognise that the exact processing steps may differ depending on the requirements of each layer. Each patterned layer comprises multiple repetitions of the same pattern 311, 321, 331, 341, 351, 361 and the patterns are arranged as a two-dimensional array. As a result, the substrate 300 comprises a two-dimensional array of copies of the same pattern 311, 321, 331, 341, 351, 361. The pattern 311, 321, 331, 341, 351, 361, when processed, results in a three-dimensional stack, formed from multiple processed layers. In other words, by repeatedly exposing and processing the substrate as discussed above, a stack of layers is built up (in the z direction) with each layer having a pattern (in the x & y direction) with material present in some regions of the pattern and not present in other regions of the pattern.

Each layer of the multiple processed layers may comprise different materials and/or each may have a different reflectivity. Additionally or alternatively, structures (or the density of structures) in the layers may impact the reflectivity. For example, lines (or the density of lines) in a layer in one region may result in a different reflectivity to a second region with different lines or a different density of lines. A structure provided at one part of the pattern may not be provided at another part of the pattern. For example, the pattern 311 contains a circular structure 313, a square structure 315, and a rectangular structure 317 (such structures are for exemplary purposes only and other structures e.g. lines, pillars and/or holes may be provided). A first layer comprises circular structure 313, below which is provided a second layer comprising rectangular structure 317, below which is provided a third layer comprising square structure 315. Due to differing reflectivities of layers that comprise each of the structures 313, 315, 317, a height measuring optical sensor may detect different measurement errors when measuring the height of each of the structures 313, 315, 317. In other words, even if the height of the surface of the substrate 300 is uniform, a height measuring optical sensor may measure different heights of the surface of the substrate 300.

A pattern (e.g. the pattern 311) may be referred to as a field (or exposure field), indicating an area which will be exposed by the lithographic apparatus LA to form the next layer of the pattern 311. Each field may comprise one or more dies.

As each field 311, 321, 331, 341, 351, 361 is patterned using lithographic light patterned by the same masks, each respective field is identical (or approximately identical). Accordingly, a point in a first area (e.g. the field 311) may have a first reflectivity the same as a second reflectivity of a corresponding point in a second area (e.g. the field 321). Likewise, where the substrate 300 comprises one or more layers, the layers provided at a point (i.e. at x-y coordinate) in a first volume (e.g. the field 311) may be the same layers as the layers provided at a corresponding point in a second volume (e.g. the field 321).

By determining a property of one point of the substrate W in a first field (i.e. a region of interest), the property for corresponding points in other fields may be inferred. The property may be the calibration correction needed for the level sensor LS to accurately measure the height of the surface of the substrate W. As an alternative, the property may be the height of the surface of the substrate W (as discussed further below).

FIG. 4 depicts a flow diagram for a method 400 for calibrating a height measuring optical sensor. At step 401, a first height is determined using a height measuring optical sensor. At step 402, a second height is determined using a scanning probe microscope. At step 403, a calibration map is determined for the height measuring optical sensor.

The method 400 may comprise determining a region of interest. For example, referring to the example substrate 300 (comprising six fields 311, 321, 331, 341, 351), the field 311 may be determined as the region of interest. The area of a substrate W corresponding to each field may be determined by the final pattern required on the substrate W. In a first example, a substrate 300 (of a certain size) may be exposed by two hundred fields and in a second example a substrate 300 (of the same certain size) may be exposed by three hundred fields. A region of interest determined for the first example substrate may correspond to a different area than the area corresponding to a region of interest determined for the second example substrate. As an alternative, the region of interest may correspond to multiple fields and/or the entire substrate. The region of interest may correspond to a single die, or alternatively, multiple dies. For example, each field may correspond to multiple dies and the region of interest may correspond to the same multiple dies. Where a field contains multiple dies, the region of interest may be one die. The region of interest may be one of a plurality of regions of interest.

At step 401, a first height is determined using a height measuring optical sensor. The first height may be determined for a point in the region of interest. The height measuring optical sensor may be a level sensor LS (as described above). The height measuring optical sensor may make use of UV and/or visible radiation. Determining the first height using the height measuring optical sensor 401 may comprise measuring the first height.

The method 400 may further comprise determining a position (i.e. an x and a y coordinate) of the point. The coordinates of the point may be stored as local coordinates (i.e. in a coordinate system local to the region of interest) or as global coordinates (and, optionally, converted to a coordinate system local to the region of interest).

At step 402, a second height is determined using a scanning probe microscope. The second height may be determined for the same point in the region of interest as the point for which a first height was determined. The scanning probe microscope may be an atomic force microscope (AFM), a near-field scanning optical microscope (NSOM), a scanning tunneling microscope (STM), a scanning electro-chemical microscope (SECM) or any other device which has a lower sensitivity to sublayer structures (relative to upper layer structures), such as e.g. a white light interferometry system, a digital holographic microscope, an air gauge arrangement or a confocal senor, capable to extract the height at the top and bottom surfaces of a layer of resist.

Determining the second height using the scanning probe microscope 402 may comprise measuring a height of the surface at a single point (e.g. the same point in the region of interest as the point for which a first height was determined). Alternatively, determining the second height using the scanning probe microscope 402 may comprise measuring multiple measurements and calculating an average. For example, the height of the surface at a single point may be measured multiple times by a scanning probe microscope. Additionally or alternatively, the height of the surface at multiple points (i.e. points nearby, and optionally including, the same point in the region of interest as the point for which a first height was determined) may be measured by a scanning probe microscope. Additionally or alternatively, the scanning probe microscope may be one of a plurality of scanning probe microscopes and each scanning probe microscope of the plurality of scanning probe microscopes may provide one or more measurements. Calculating an average may comprise determining a mean of the multiple measurements. Beneficially, measuring multiple measurements and calculating an average may help ensure that the second height corresponds to the first height regardless of any difference between the spatial resolution (i.e. resolution across the x and y dimensions when measuring the z dimension) of the height measuring optical sensor and the scanning probe microscope.

The point in the region of interest (i.e. the point for which a first and a second height is determined) may be one of a plurality of points (each of the plurality of points being located in the same region of interest or, alternatively, located in different regions of interest). In other words, a first height may be determined for multiple points and a second height may be determined for the same multiple points.

Steps 401 and 402 may be carried out in any order. In other words, the first height may be determined by the height measuring optical sensor before, or after, the second height is determined by the scanning probe microscope.

At step 403, a calibration map is determined for the height measuring optical sensor. In other words, for each point for which a first height (determined using the height measuring optical sensor) and a second height (determined using the scanning probe microscope), a calibration value may be determined (by assuming the second height is a ‘true’ value, free of, or with reduced, measurement errors arising from optical effects). The calibration value may also be referred to as an offset. The calibration map may comprise a plurality of calibration values and, for each calibration value, a corresponding coordinate. Determining the calibration map may comprise populating the calibration map with calibration values and corresponding coordinates. The corresponding calibration value may be determined (for each point) by subtracting the first height from the second height. For example, for a point, the first height may be determined as 50 nm, the second height may be determined as 60 nm and the corresponding calibration value may be determined as +10 nm. In other words, the height measuring optical sensor has determined the height at the point as 10 nm less than the ‘true’ value and the height determined by the height measuring optical sensor at the same (or similar points) should be corrected by increasing the value by 10 nm. The coordinate (for each calibration value) may be a local coordinate (e.g. local to the region of interest). By determining a calibration value for each point (of the plurality of points) in the region of the interest, a calibration map may be determined. Points may be distributed across the region of interest. Accordingly, the calibration map may comprise a plurality of calibrations values corresponding to point distributed across the region of interest.

Determining the calibration map 403 may comprise the use of interpolation. For example, if a first point and a second point have calibration values of +10 nm and +20 nm, respectively, a third point halfway between the first and second point may be determined as having a calibration value of +15 nm. Additionally or alternatively, interpolation may be used when the calibration map is applied.

Regions on a substrate that correspond to the calibrated region of interest are expected to interact with radiation of the height measuring optical sensor in the same way. Thus, a calibration map determined for the region of interest may be also be beneficially applied to any other region that corresponds to the region of interest. For example, if the region of interest corresponds to a field, the calibration map may be applied to other corresponding fields across the substrate. The calibration map may comprise data corresponding to the region of interest of the substrate W. For a point in a field corresponding to the region of interest, a respective calibration value may be determined. In other words, the calibration map may comprise data corresponding to a single field and the calibration values for other fields may be inferred for the other fields.

The method 400 may further comprise applying the calibration map. Applying the calibration map may comprise determining calibration values for a point (in a field). As discussed below, applying the calibration map may comprise calibrating the height of the substrate W as measured by the height measuring optical sensor and, optionally, adjusting the height of the substrate W by moving the substrate support WT accordingly. In examples comprising multiple regions of interest, the region of interest corresponding to the field may be determined. The region of interest corresponding to the field may be determined by identification of matching features, use of stored data such as identifiers, determination of coordinates or otherwise.

A position of the point (i.e. the point to which the calibration map is to be applied) may be determined. For example, the position of the point may be determined by measuring coordinates (e.g. x, y coordinates) of a point on a surface of substrate W being (or to be) measured by a height measuring optical sensor. The point on the surface of the substrate W may be a point on the top surface of one or more processed layers and/or features of the substrate W.

A calibration value from the calibration map corresponding to the point may be identified. For example, the position of the point may be converted into a local coordinate (local to the field).

Local coordinates for the field may correspond to local coordinates for the region of interest. Local coordinates may allow a calibration value to be determined from the calibration map. For example, if the point has a local (to the field) coordinate of (4, 5), the calibration value for the local (to the region of interest) coordinate of (4, 5) in region of interest may be used for the point and determined from the calibration map. As discussed above, interpolation may be used when identifying a calibration value corresponding to the point. The calibration value corresponding to the point may be identified in a different way. For example, a calibration value from the calibration map with coordinates closest to the coordinates of the point may be identified.

Applying the calibration map may comprise calibrating a measurement provided by the height measuring optical sensor. For example, if the height measuring optical sensor measures the height of a point of the surface of the substrate W as 5 nm and the corresponding calibration value is +2 nm, the calibrated measurement may be 7 nm. In other words, the calibration provides a correction for the measurement and the calibrated measurement may also be referred to as a corrected measurement. As the calibration values are provided by the calibration map, the calibration value may have a different value at different points on the substrate W.

The calibrated height measurement (provided by the height measuring optical sensor and by application of the calibration map) may be used in any conventional way. For example, the calibrated height measurement may be used to determine how to change the elevation (i.e. the z coordinate) of the substrate W. The elevation of the substrate may be changed, for example, by adjusting a height of the substrate support WT to which the substrate W is mounted. Additionally or alternatively, the resulting measurement may be used to adjust a focus of the radiation beam B, for example, by adjusting one or more optical elements of the lithographic apparatus LA.

The determination of how to change the elevation of the substrate W may not depend entirely on a single (calibrated or uncalibrated) height measurement. As is known in the art, due to the arrangement of the lithographic apparatus LA, multiple areas within a field (for example, multiple areas aligned with a common y coordinate) may be exposed to the radiation at a single time.

Typically, multiple height measurements (i.e. uncalibrated measurements provided by the height measuring optical sensor) corresponding to points across the multiple areas may be used to provide an average height measurement used to determine the change of elevation of the substrate W. Calibrated height measurements may also be used in this way such that a single change of elevation of the substrate W is determined for use when the multiple areas are exposed to the radiation beam B.

As discussed above, a lithographic apparatus LA may comprise a level sensor LS (i.e. a height measuring optical sensor). The lithographic apparatus LA may further comprise one or more scanning probe microscopes to allow the method 400 to be performed. For example, a plurality of scanning probe microscopes may be provided and arranged into an array such that the second height may be determined for a plurality of points (within the region of interest) at a single time, thereby decreasing the time taken to calibrate the first sensor. Additionally or alternatively, in the example where the second height (for a single point) comprises measuring multiple measurements across an area and calculating an average, the plurality of scanning probe microscopes may allow the multiple measurements to be measured at a single time.

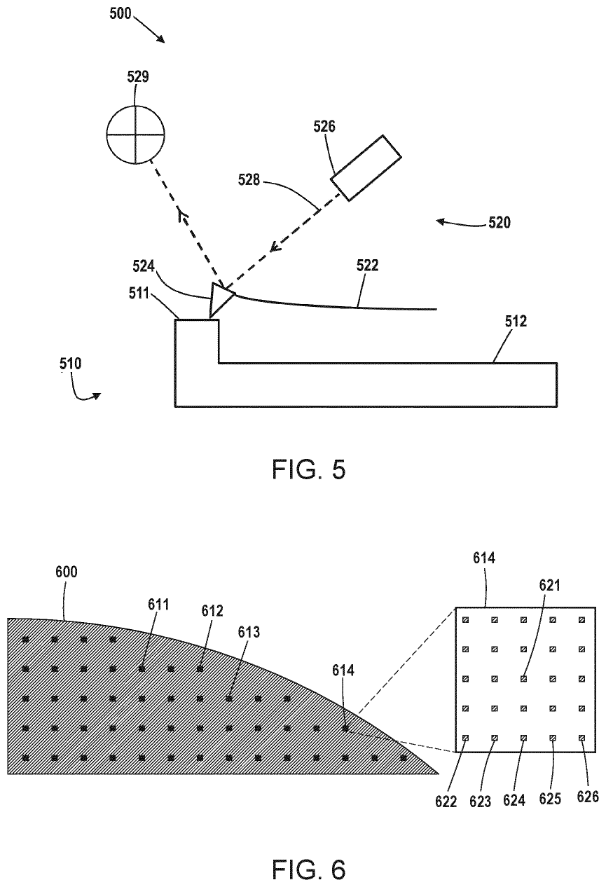

FIG. 5 depicts an example scanning probe microscope 520. While the example scanning probe microscope 520 depicted in FIG. 5 is an atomic force microscope (AFM) 520, as will be clear to the skilled person, other scanning probe microscopes may be suitable for use in the method 400.

The AFM 520 comprises a tip 524 provided on an end of a cantilever 522. A light source (e.g. a laser) 526 provides a radiation beam 528 that is reflected off a backside of the tip 524 towards a photodiode 529. Alternatively, the radiation beam 528 may be reflected off a side of the cantilever 522 near to the backside of the tip 524.

In use, the height of the tip 524 is varied (e.g. by adjusting a bend in the cantilever 522) such that the tip 524 contacts a surface 511 of a sample 510. As the height of the tip 524 is varied, the intensity of the radiation beam 528 received by the photodiode 529 is varied and the height of the surface 511 of the sample 510 can thus be inferred. The sample 510 and the AFM 520 are moved (e.g. horizontally in FIG. 5) with respect to one another, such that the AFM may measure the height of the sample 510 at different points. For example, the tip 524 may contact a first surface 511 of the sample 510 and a first intensity of the radiation beam 528 may be detected by the photodiode 529 to measure a first height of the first surface 511. The AFM 520 may then be moved. The tip 524 may then contact a second surface 512 of the sample 510 and a second intensity of the radiation beam 528 may be detected by the photodiode 529 to measure a second height of the second surface 512. In this way, the AFM 520 may measure the height of the surface of the sample 510 at different points. While the AFM 520 has been described as operating in a contact mode, as is known in the art, the AFM may be run in different modes. For example, the AFM 520 may be operated in a tapping mode wherein the tip 524 is raised up and lowered down repeatedly, a contact mode wherein the tip 524 continuously contacts the surface of the sample 510 or a non-contact mode wherein the tip 524 is in continuous close proximity (but not in contact) with the surface of the sample 510. Any mode, including those described here, may be applied to any embodiment of the invention.

FIG. 6 depicts an example substrate 600. While the measurements have thus-far been described in relation to points, as discussed above, the scanning probe microscope and, in particular, the height measuring optical sensor may each have a different, non-zero spatial resolution. In other words, the beam of radiation BE1 (provided by the height measuring optical sensor) may have a relatively wide cross-sectional area (i.e. the area transverse to the direction of the beam of radiation BE1) and thus the height (measured by the height measuring optical sensor) may correspond to a relatively wide cross-sectional area of the surface of the substrate W. The scanning probe microscope may make each measurement across a relatively small area (e.g. determined by a sharpness of the tip 524). Accordingly, the scanning probe microscope may take multiple measurements within the region to which a measurement taken by the height measuring optical sensor corresponds. Multiple first measurement areas 611, 612, 613, 614 are indicated on the substrate 600, each of the first measurement areas 611, 612, 613, 614 corresponding to a first height measurement (i.e. measured by the height measuring optical sensor) and indicating the spatial resolution of the height measuring optical sensor. FIG. 6 depicts an enlarged view of the first measurement area 614 with multiple second measurement points 621, 622, 623, 624, 625, 626 (i.e. possible points that could be measured by the scanning probe microscope). The scanning probe microscope may take a single measurement corresponding to the first measurement area 614, for example at second measurement point 621 (at the center of the first measurement area 614). Alternatively, as discussed above, the scanning probe microscope (or multiple scanning probe microscopes) may measure multiple second measurements and an average may be calculated.

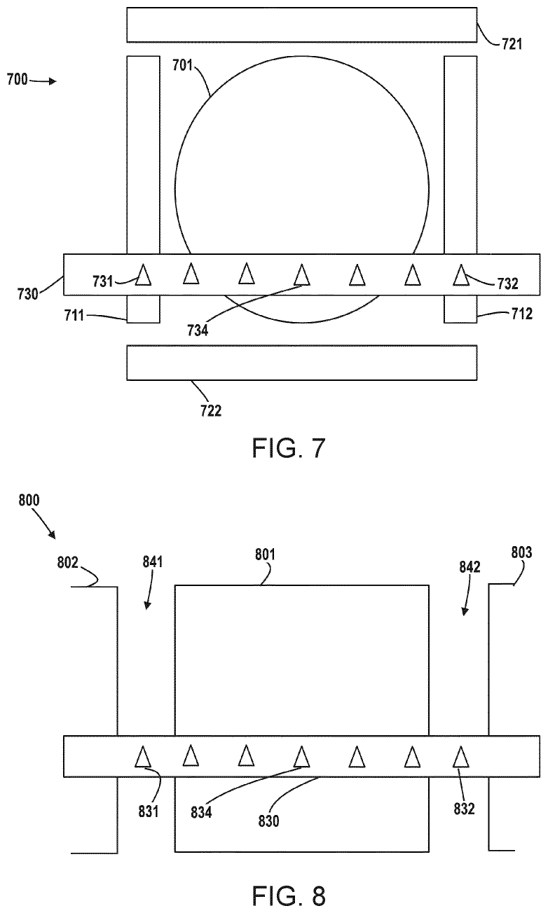

FIG. 7 depicts an example array of scanning probe microscopes 730 configured to measure a height of a substrate 701.

A plurality of scanning probe microscopes 731, 732, 734 are provided to measure a height of the surface of the substrate 701 at a plurality of points. The plurality of scanning probe microscopes 731, 732, 734 may be arranged into an array as shown in FIG. 7. Alternatively, the plurality of scanning probe microscopes 731, 732, 734 may be arranged into a lattice. For example, a first row of scanning probe microscopes may extend in a first direction, a second row of scanning probe microscopes may extend in the first direction and the second row may be offset to the first row in the first direction and a second direction perpendicular to the first.

References rails 711, 712, 713, 714 may be provided on each side of the substrate 701. Reference rails 711, 712 extend substantially in a first direction and reference rails 713, 714 extend substantially in a second direction. The reference rails 711, 712, 713, 714 may allow a reference height to be determined. Other markers may be provided to determine a reference height to be determined, for example, a mark or tab. An example of such a mark is the substrate alignment marks P1, P2 (depicted in FIG. 1).

Each of the scanning probe microscopes 731, 732, 734 may be fixed to a rigid member 730 that extends from a first reference rail 711, across to the substrate 701 to a second reference rail 712.

A plurality of the scanning probe microscopes 734 are provided to determine a height of a surface of the substrate. The rigid member 730 may be moved relative to the substrate 701 to allow the plurality of scanning probe microscopes 734 to determine a height of the surface of the substrate at multiple points. For example, when the scanning probe microscopes 731, 732, 734 are arranged into a single line extending in a first direction the rigid member 730 may be moved relative to the substrate 701 in a second direction, perpendicular to the first. Alternatively, the substrate 701 may be moved relative to the rigid member 730.

One or more of the scanning probe microscopes 731, 732 may be provided to determine the height of reference markers (i.e. the reference rails 711, 712). By determining the height of reference markers and determining the height of the surface of the substrate at plurality of points, the relative height of the surface of the substrate may be determined. In other words, the relative height may be the height relative to the reference markers.

FIG. 8 depicts an example array of scanning probe microscopes 830 configured to measure a height of a field 801. The field 801 is shown with associated scribe lines 841, 842 and neighbouring fields 802, 803. The array of scanning probe microscopes 830 is arranged similar to the array of scanning probe microscopes 830. Reference markers may be provided in the scribe lanes 841, 842. The one or more of the scanning probe microscopes 831, 832 provided to determine the of reference markers are arranged to determine the height of reference markers in the scribe lanes 841, 842.

Similar to the method 400, the determined heights (and corresponding coordinates) may be used to determine a height map. The height map may correspond to the whole of the substrate, or alternatively, a field.

Once a height map has been determined for a single field, the height of the surface of the substrate in corresponding fields may be inferred. In other words, if a first field is patterned with a pattern and a second field is patterned with an identical pattern, the height measurements of the first field may also corresponding to the second field.

While FIG. 8 depicts the array of scanning probe microscopes 830 configured to measure a height of a field 801, the field 801 (and neighbouring fields 802, 803) may alternatively by a die and neighbouring dies, respectively. Accordingly, where the height map has been determined for a single die, the height of the surface of the substrate in corresponding dies may be inferred.

A lithographic apparatus may be provided with plurality of scanning probe microscopes to allow the heights of the surface of a substrate to be determined.

A lithographic tool (i.e. a tool configured to pattern a substrate with radiation) may be provided with plurality of scanning probe microscopes and a processor to allow heights of the surface of a substrate to be determined. Such a lithographic tool may allow the methods disclosed here-in to be performed. For example, the lithographic tool may be used to determine, using a scanning probe microscope, the second heights of a substrate (i.e. step 402). The substrate may be provided in a lithographic apparatus comprising a height measuring optical sensor allow the first heights to be performed (i.e. step 401). The first and second heights may then be used to determine a calibration map for the height measuring optical sensor (i.e. step 403).

The lithographic tool may be further provided with a height measuring optical sensor to allow the method 400 to be performed entirely by the lithographic tool. The lithographic tool may be an inline tool i.e. the tool may be used as part of a production process and used for each substrate produced. Alternatively, the lithographic tool may be an offline tool i.e. the tool may be used for some, but not all, substrates produced in the production process.

Metrology tools are tools configured to measure a characteristic of a lithographic apparatus or substrate patterned by a lithographic apparatus. For example, a metrology tool may monitor the overlay and/or focus performance of a lithographic apparatus by measuring a substrate patterned by the lithographic apparatus. A metrology tool may be provided with plurality of scanning probe microscopes and a processor to allow heights of the surface of a substrate to be determined. The metrology tool (or apparatus) may be further provided with a height measuring optical sensor to allow the method 400 to be performed.

A system may be provided with a lithographic apparatus and plurality of scanning probe microscopes and a processor to allow heights of the surface of a substrate to be determined. The system may be further provided with a height measuring optical sensor to allow the method 400 to be performed.

As discussed, lithographic apparatus LA may be provided with two or more substrate supports WT (i.e. a ‘dual stage’). In such dual-stage lithographic apparatus LA, plurality of scanning probe microscopes may be provided such that the methods described herein may be performed before or after the substrate W has been exposed to the radiation beam B. In other words, while a first substrate W (on a first substrate support WT) is being exposed to the radiation beam B, a second substrate W (on a second substrate support WT) may be measured by the plurality of scanning probe microscopes before, or after, the second substrate W is exposed to the radiation beam B.

While the methods described herein have been described in relation to a substrate W that has, or will be, exposed to lithographic radiation (i.e. the radiation beam B), as will be clear to the skilled person, the methods (and corresponding apparatus) may beneficially be adapted for use with substrates that are not exposed to lithographic radiation.

Likewise, while the methods described herein have been described in relation to DUV lithographic radiation, as will be clear to the skilled person, the methods (and corresponding apparatus) may be beneficially adapted for use with EUV lithographic radiation (and corresponding apparatus).

Although specific reference may be made in this text to the use of a lithographic apparatus in the manufacture of ICs, it should be understood that the lithographic apparatus described herein may have other applications. Possible other applications include the manufacture of integrated optical systems, guidance and detection patterns for magnetic domain memories, flat-panel displays, liquid-crystal displays (LCDs), thin-film magnetic heads, etc.

The skilled person will appreciate that, in the context of such alternative applications, any use of the terms “wafer” or “die” herein may be considered as synonymous with the more general terms “substrate” or “target portion”, respectively. The substrate referred to herein may be processed, before or after exposure, in for example a track (a tool that typically applies a layer of resist to a substrate and develops the exposed resist), a metrology tool and/or an inspection tool. Where applicable, the disclosure herein may be applied to such and other substrate processing tools. Further, the substrate may be processed more than once, for example in order to create a multi-layer IC, so that the term substrate used herein may also refer to a substrate that already contains multiple processed layers.

Although specific reference may be made in this text to embodiments of the invention in the context of a lithographic apparatus, embodiments of the invention may be used in other apparatus. Embodiments of the invention may form part of a mask inspection apparatus, a metrology apparatus, or any apparatus that measures or processes an object such as a wafer (or other substrate) or mask (or other patterning device). These apparatus may be generally referred to as lithographic tools. Such a lithographic tool may use vacuum conditions or ambient (non-vacuum) conditions.

Although specific reference may have been made above to the use of embodiments of the invention in the context of optical lithography, it will be appreciated that the invention, where the context allows, is not limited to optical lithography and may be used in other applications, for example imprint lithography.

Where the context allows, embodiments of the invention may be implemented in hardware, firmware, software, or any combination thereof. Embodiments of the invention may also be implemented as instructions stored on a machine-readable medium, which may be read and executed by one or more processors. A machine-readable medium may include any mechanism for storing or transmitting information in a form readable by a machine (e.g., a computing device). For example, a machine-readable medium may include read only memory (ROM); random access memory (RAM); magnetic storage media; optical storage media; flash memory devices; electrical, optical, acoustical or other forms of propagated signals (e.g. carrier waves, infrared signals, digital signals, etc.), and others. Further, firmware, software, routines, instructions may be described herein as performing certain actions. However, it should be appreciated that such descriptions are merely for convenience and that such actions in fact result from computing devices, processors, controllers, or other devices executing the firmware, software, routines, instructions, etc. and in doing that may cause actuators or other devices to interact with the physical world.

While specific embodiments of the invention have been described above, it will be appreciated that the invention may be practiced otherwise than as described. The descriptions above are intended to be illustrative, not limiting. Thus it will be apparent to one skilled in the art that modifications may be made to the invention as described without departing from the scope of the claims set out below. Other aspects of the invention are set-out as in the following numbered clauses.
1. A method for calibrating a height measuring optical sensor for a substrate in a lithographic apparatus comprising:
   determining, using the height measuring optical sensor, a first height of a surface of the substrate within a region of interest;
   determining, using a scanning probe microscope, a second height of the surface of the substrate within the region of interest; and
   determining a calibration map for the height measuring optical sensor for the region of interest, by comparing the first height and the second height.
2. The method of clause 1 further comprising applying the calibration map for other regions of the substrate that corresponding to the region of interest.
3. The method of any preceding clause wherein the scanning probe microscope is an atomic force microscope (AFM) or a near-field scanning optical microscope (NSOM).
4. The method of any preceding clause wherein the scanning probe microscope is one of a plurality of scanning probe microscopes.
5. The method of any preceding clause wherein determining the second height comprises: measuring, using the scanning probe microscope, a height of the surface of the substrate within the region of interest.
6. The method of any preceding clause wherein determining the second height comprises:
   measuring, using the scanning probe microscope, plurality of heights of the surface of the substrate for the at least on region of interest; and
   calculating an average of the plurality of heights.
7. A lithographic apparatus comprising:
   a height measuring optical sensor configured to determine a first height of a surface of the substrate within a region of interest;
   a scanning probe microscope configured to determine a second height of the surface of the substrate within the region of interest; and
   a processor configured to determine a calibration map for the height measuring optical sensor for the region of interest, by comparing the first height and the second height.
8. A system comprising:
   a lithographic apparatus comprising a height measuring optical sensor configured to determine a first height of a surface of the substrate within a region of interest;
   a scanning probe microscope configured to determine a second height of the surface of the substrate within the region of interest; and
   a processor configured to determine a calibration map for the height measuring optical sensor for the region of interest, by comparing the first height and the second height.
9. A lithographic tool comprising:
   a height measuring optical sensor configured to determine a first height of a surface of the substrate within a region of interest;
   a scanning probe microscope configured to determine a second height of the surface of the substrate within the region of interest; and
   a processor configured to determine a calibration map for the height measuring optical sensor for the region of interest, by comparing the first height and the second height.
10. A metrology tool comprising:
   a height measuring optical sensor configured to determine a first height of a surface of the substrate within a region of interest;
   a scanning probe microscope configured to determine a second height of the surface of the substrate within the region of interest; and
   a processor configured to determine a calibration map for the height measuring optical sensor for the region of interest, by comparing the first height and the second height.
11. Computer-readable storage medium comprising instructions which, when executed by a computer, cause the computer to carry out the method of clauses 1 to 6.
12. A calibration map comprising data corresponding to a region of interest of a substrate wherein the substrate comprises a plurality of regions, each region of the plurality of regions having been patterned with an identical pattern.
13. A method of determining a height of a surface of a substrate comprising:
   determining a height of a reference point; and
   determining, using a plurality of scanning probe microscopes, the height of the surface of the substrate at one or more points.
14. The method of clause 13 wherein the determined height of the surface of the substrate at the one or more points is a relative height, relative to the height of a reference point.
15. A lithographic apparatus comprising a plurality of scanning probe microscopes configured to:
   determine a height of a reference point; and
   determine the height of the surface of the substrate at one or more points.
16. A metrology tool comprising a plurality of scanning probe microscopes configured to:
   determine a height of a reference point; and
determine the height of the surface of the substrate at one or more points.

1-16. (canceled)

17. A method comprising:
determining, using a height measuring optical sensor, a first height of a surface of a substrate within a region of interest;
determining, using one of a plurality of scanning probe microscopes, a second height of the surface of the substrate within the region of interest; and
determining a calibration map for the height measuring optical sensor for the region of interest, by comparing the first height and the second height.

18. The method of claim 17, further comprising applying the calibration map for other regions of the substrate that corresponding to the region of interest.

19. The method of claim 17, wherein the one of the plurality of scanning probe microscopes is an atomic force microscope (AFM) or a near-field scanning optical microscope (NSOM).

20. The method of claim 17, wherein the determining the second height comprises:
measuring, using the scanning probe microscope, a height of the surface of the substrate within the region of interest.

21. The method of claim 17, wherein the determining the second height comprises:
measuring, using the scanning probe microscope, a plurality of heights of the surface of the substrate for the at least on region of interest; and
calculating an average of the plurality of heights.

22. An apparatus comprising:
a height measuring optical sensor configured to determine a first height of a surface of a substrate within a region of interest;
a plurality of scanning probe microscopes configured to determine a second height of the surface of the substrate within the region of interest; and
a processor configured to determine a calibration map for the height measuring optical sensor for the region of interest, by comparing the first height and the second height.

23. The apparatus of claim 22, wherein the plurality of scanning probe microscopes is a plurality of atomic force microscopes (AFM) or near-field scanning optical microscopes (NSOM).

24. A method comprising:
determining a height of a reference point; and
determining, using a plurality of scanning probe microscopes, the height of a surface of a substrate at one or more points.

25. The method of claim 24, wherein the height of the surface of the substrate at the one or more points is a relative height, relative to the height of a reference point.
